(19) United States
(12) Patent Application Publication
(10) Pub. No.: US 2018/0129134 A1
(43) Pub. Date: May 10, 2018

(54) PRODUCTION PROCESS FOR SOLDER ELECTRODE AND USE THEREOF

(71) Applicant: JSR CORPORATION, Tokyo (JP)

(72) Inventors: JUN MUKAWA, Minato-ku, Tokyo (JP); Seiichirou TAKAHASHI, Minato-ku, Tokyo (JP); Kouichi HASEGAWA, Minato-ku, Tokyo (JP); Shirou KUSUMOTO, Minato-ku, Tokyo (JP); Yoshikazu YAMAGUCHI, Minato-ku, Tokyo (JP)

(73) Assignee: JSR CORPORATION, Tokyo (JP)

(21) Appl. No.: 15/572,163

(22) PCT Filed: Apr. 28, 2016
(86) PCT No.: PCT/JP2016/063365

§ 371 Date: Nov. 7, 2017

(30) Foreign Application Priority Data
May 8, 2015 (JP) 2015-095670

(51) Int. Cl. G03F 7/023; B23K 1/20; G03F 7/40; H05K 3/34; H01L 23/00; H05K 3/40

(52) U.S. Cl. CPC G03F 7/023; B23K 1/20; H05K 3/4038; H05K 3/3468; H01L 24/11; G03F 7/40

(57) ABSTRACT

The present invention relates to a production process for a solder electrode, including: a step (1) of forming a coating film of a photosensitive resin composition on a substrate having an electrode pad; a step (2) of forming resist having an opening in a region corresponding to the electrode pad by selectively exposing the coating film to light and further developing the film; and a step (3) of filling the opening with molten solder, in which the photosensitive resin composition contains at least a benzoxazole precursor. According to the production process for the solder electrode of the present invention, development of cracks on a resist surface can be prevented, and solder filling capability can be improved, even when the resist receives high heat during solder filling as in an IMS method, and therefore the solder electrode adapted for the purpose can be appropriately produced.

### TECHNICAL FIELD

The present invention relates to a production process for a solder electrode, a solder electrode, a production process for a laminate, a laminate, an electronic component and a photosensitive resin composition.

### BACKGROUND ART

An IMS (injection molded solder) method is one of methods for forming a solder pattern (solder bump). As the methods for forming the solder pattern on a substrate such as a wafer, a solder paste method, a plating method and the like have been used so far. In these methods, however, control of a height of the solder bump is difficult, and in addition thereto, there have been restrictions of incapability of freely selecting a solder composition, or the like. In contrast, the IMS method is known to have an advantage of being free from these restrictions.

As shown in Patent literature 1 to 4, the IMS method is a method being characterized in that molten solder is injected into a space between resist patterns, while a nozzle from which the molten solder can be injection-molded is brought into close contact with resist.

### CITATION LIST

### Patent Literature

Patent literature 1: Japanese Patent Laid-Open Publication No. 1994-055260

Patent literature 2: Japanese Patent Laid-Open Publication No. 2007-294954

Patent literature 3: Japanese Patent Laid-Open Publication No. 2007-294959

Patent literature 4: Japanese Unexamined Patent Application Publication (Translation of PCT Application) No. 2013-520011

### SUMMARY OF INVENTION

An IMS method is performed by pressing an IMS head heated to a high temperature, ordinarily to 250° C. or more, onto a resist surface in order to fill openings with molten solder. Therefore, there has been a problem of reduction of solder filling capability because a load caused by high heat is applied onto the resist surface to develop cracks on the resist surface or blisters of resist.

An object of the present invention is to provide a technology according to which the solder filling capability can be improved by preventing development of the cracks on the resist surface, even when the resist receives high heat during solder filling as in the INS method.

### Solution to Problem

A production process for a solder electrode according to the present invention includes: a step (1) of forming a coating film of a photosensitive resin composition on a substrate having an electrode pad; a step (2) of forming resist having an opening in a region corresponding to the electrode pad by selectively exposing the coating film to light and further developing the film; and a step (3) of filling the opening with molten solder, wherein the photosensitive resin composition contains at least a benzoxazole precursor.

In the production process for the solder electrode, the benzoxazole precursor preferably has a structure derived from dicarboxylic acid, and a structure derived from dihydroxydiamine, and the dicarboxylic acid is further preferably aromatic dicarboxylic acid and the dihydroxydiamine is further preferably aromatic diamine.

In the production process for the solder electrode, the photosensitive resin composition can further contain a photosensitive agent, and as the photosensitive agent, a naphtoquinonediazide compound can be applied.

The production process for the solder electrode can further include a step (4) of removing the resist.

A solder electrode of the present invention is a solder electrode produced by the production process for the solder electrode.

A first production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of forming a solder electrode by filling the opening with molten solder while heating the molten solder; and a step (5) of forming an electrical connection structure of the electrode pad of the first substrate and an electrode pad of a second substrate having the electrode pad through the solder electrode, wherein the photosensitive resin composition contains at least a benzoxazole precursor.

A second production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of forming a solder electrode by filling the opening with molten solder while heating the molten solder; a step (4) of removing the resist after the step (3); and a step (5) of forming an electrical connection structure of the electrode pad of the first substrate and an electrode pad of a second substrate having the electrode pad through the solder electrode after the step (4), wherein the photosensitive resin composition contains at least a benzoxazole precursor.

A laminate of the present invention is a laminate produced by the first production process for the laminate or the second production process for the laminate.

An electronic component of the present invention is an electronic component having the laminate.

A photosensitive resin composition for injection molding solder according to the present invention contains at least a benzoxazole precursor.

### Advantageous Effects of Invention

According to a production process for a solder electrode of the present invention, development of cracks on a resist surface can be prevented, and solder filling capability can be improved, even when resist receives high heat during solder filling as in an IMS method, and therefore the solder electrode adapted for the purpose can be appropriately produced.

According to a production process for a laminate of the present invention, a solder electrode adapted for the purpose can be appropriately produced by an IMS method, and therefore the laminate having an electrical connection structure can be appropriately produced.

### BRIEF DESCRIPTION OF DRAWINGS

FIGS. 1(1) to (4) are each a schematic sectional view of a structure containing a substrate in each step in a production process for a solder electrode according to the present invention.

FIGS. 2(5-1) and (5-2) are each a schematic sectional view of a laminate according to the present invention.

### DESCRIPTION OF EMBODIMENTS

<Production Process for a Solder Electrode>

A production process for a solder electrode according to the present invention includes: a step (1) of faulting a coating film of a photosensitive resin composition on a substrate having an electrode pad; a step (2) of forming resist having an opening in a region corresponding to the electrode pad by selectively exposing the coating film to light and further developing the film; and a step (3) of filling the opening with molten solder, wherein the photosensitive resin composition contains at least a benzoxazole precursor.

The production process for the solder electrode according to the present invention is different from a conventional method in that the photosensitive resin composition used in the step (1) contains the benzoxazole precursor. Operation in the steps (1) to (3) can be performed in the same manner as in the conventional method.

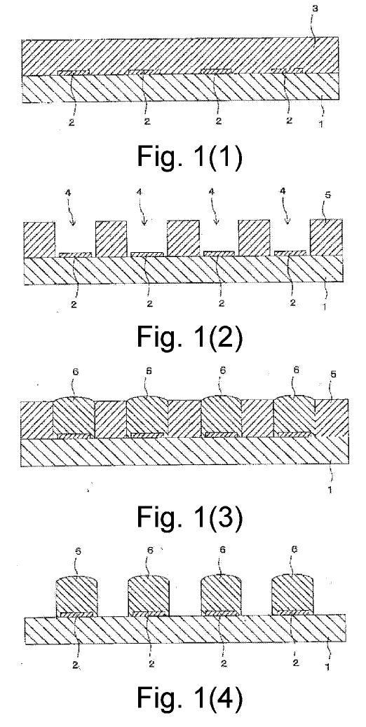

Hereinafter, the production process for the solder electrode according to the present invention will be described with reference to FIG. 1.

### (Step (1))

In the step (1), as shown in FIG. 1(1), a coating film 3 of a photosensitive resin composition is formed on a substrate 1 having an electrode pad 2.

Specific examples of the substrate 1 include a semiconductor substrate, a glass substrate and a silicon substrate, and a substrate formed by providing various metal films on a surface of a semiconductor board, a glass board and a silicon board. The substrate 1 has a large number of electrode pads 2.

The coating film 3 is formed by coating a photosensitive resin composition onto the substrate 1, or the like. A method for coating the photosensitive resin composition thereonto is not particularly limited, and specific examples thereof can include a spraying method, a roll coating method, a spin coating method, a slit die coating method, a bar coating method and an inkjet method. A film thickness of the coating film 3 is ordinarily 1 to 500 μm, preferably 5 to 200 μm, and further preferably 10 to 100 μm.

The photosensitive resin composition contains at least the benzoxazole precursor. The benzoxazole precursor causes reaction within a molecule upon receiving heat, and rapidly changes to a heat-resistant structure. On this account, when the resist formed of the photosensitive resin composition is heated to a high temperature during solder filling as in the IMS method, the benzoxazole precursor contained in the resist rapidly changes to the heat-resistant structure, and therefore heat resistance is improved, and as a result, development of the cracks on the resist surface is suppressed, and solder embedding properties are conceivably improved.

The coating film formed of the photosensitive resin composition is crosslinked by exposure to light in the step (2) described later. However, a crosslinking agent contained in the photosensitive resin composition is ordinarily not completely consumed only by the exposure to light, and an unconsumed crosslinking agent remains in the resist. On this account, crosslinking of the resist is incomplete only by being exposed to light, and strength of the resist is not sufficiently enhanced. When the opening is filled with the molten solder by pressing a hot head onto the surface of the resist in this state by the IMS method, as in the conventional method, the resist fails to withstand the heat received from an IMS head, and the cracks and the blisters are conceivably developed. In contrast, in the production process for the solder electrode according to the present invention, as described above, the heat resistance of the resist is rapidly improved, and therefore neither the cracks nor the blisters are developed.

In addition, also in a conventional IMS method using a photosensitive resin composition without containing the benzoxazole precursor, a crosslinking reaction by the crosslinking agent remaining in the resist progresses by heat during filling the opening with the molten solder, and the resist is conceivably strengthened. However, a crosslinking reaction rate is low in the crosslinking agent such as polyfunctional acrylate used in the photosensitive resin composition, and therefore the cracks and the blisters are conceivably developed by the heat received from the IMS head before the crosslinking reaction sufficiently progresses.

Specific examples of the benzoxazole precursor preferably include a polybenzoxazole precursor obtained by using dicarboxylic acid and dihydroxydiamine as raw materials. Such a benzoxazole precursor is obtained by reacting dicarboxylic acid with dihydroxydiamine, and has a structure derived from dicarboxylic acid and a structure derived from dihydroxydiamine, namely, a dicarboxylic acid residue and a dihydroxydiamine residue. Such a benzoxazole precursor is formed into a particularly highly heat-resistant structure upon receiving heat, and therefore in the resist obtained from the photosensitive resin composition containing the benzoxazole precursor according to the present invention, when the resist receives high heat, development of the cracks on the surface can be further effectively prevented.

Specific examples of the dicarboxylic acid include: aromatic dicarboxylic acid such as isophthalic acid, terephthalic acid, 2,2-bis(4-carboxyphenyl)hexafluoropropane, 4,4′-biphenyldicarboxylic acid, 4,4′-dicarboxydiphenyl ether, 4,4′-dicarboxytetraphenylsilane, bis(4-carboxyphenyl) sulfone, 2,2-bis(p-carboxyphenyl) propane, 5-tert-butylisophthalic acid, 5-bromoisophthalic acid, 5-fluoroisophthalic acid, 5-chloroisophthalic acid and 2,6-naphthalene dicarboxylic acid; and aliphatic dicarboxylic acid such as 1,2-cyclobutanedicarboxylic acid, 1,4-cyclohexanedicarboxylic acid, 1,3-cyclopentanedicarboxylic acid, oxalic acid, malonic acid and succinic acid. These compounds can be used alone or in combination with two or more kinds. Among these compounds, in view of the heat resistance, aromatic dicarboxylic acid is preferable.

Specific examples of the dihydroxydiamine include: aromatic diamine such as 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, bis(3-amino-4-hydroxyphenyl)hexafluoropropane, bis (4-amino-3-hydroxyphenyl)hexafluoropropane, bis(3-amino-4-hydroxyphenyl)propane, bis(4-amino-3-hydroxyphenyl)propane, 4,6-diaminoresorcinol, 4,5-diaminoresorcinol and bis(4-amino-3-carboxyphenyl)methane. The polybenzoxazole precursor having good heat resistance is obtained by using the aromatic diamine.

As a polystyrene-equivalent weight-average molecular weight (Mw) of the benzoxazole precursor, which is measured by Gel Permeation Chromatography, is preferably 3,000 to 200,000, and further preferably 5,000 to 100,000.

A content of the benzoxazole precursor in the photosensitive resin composition is ordinarily 50% by mass or more, preferably 60 to 95% by mass, and further preferably 70 to 90% by mass, when a total solid contained in the composition is taken as 100% by mass.

The photosensitive resin composition can contain, in addition to the benzoxazole precursor, a component ordinarily contained in the photosensitive resin composition used in the conventional method.

The photosensitive resin composition may be of either a positive type or a negative type. Whether the photosensitive resin composition is of the positive type or the negative type is determined depending on a kind of a photosensitive agent contained in the photosensitive resin composition. The photosensitive resin composition, in the case of the positive type, contains, as the photosensitive agent, naphtoquinonediazide as an essential component, and in the case of the negative type, contains, as the photosensitive agent, a photoacid generator and a cationic crosslinking agent as the essential components.

The coating film containing the naphtoquinonediazide compound is sparingly soluble in an alkaline developer. However, in the naphtoquinonediazide compound, a quinonediazide group is decomposed by irradiation with light to form a carboxyl group, and the naphtoquinonediazide compound becomes easily alkali-soluble. Accordingly, the coating film containing the naphtoquinonediazide compound is changed from slight alkali-solubility to easy alkali-solubility by irradiation with light.

The naphtoquinonediazide compound is an ester compound between a compound having one or more phenolic hydroxyl groups and 1,2-naphtoquinonediazide-4-sulfonic acid or 1,2-naphtoquinonediazide-5-sulfonic acid.

Specific examples of the naphtoquinonediazide compound include an ester compound between 4,4′-dihydroxydiphenylmethane, 4,4′-dihydroxydiphenyl ether, 2,3,4-trihydroxybenzophenone, 2,3,4,4′-tetrahydroxybenzophenone, 2,3,4,2′,4′-pentahydroxybenzophenone, tris(4-hydroxyphenyl)methane, tris(4-hydroxyphenyl)ethane, 1,1-bis(4-hydroxyphenyl)-1-phenylethane, 1,3-bis[1-(4-hydroxyphenyl)-1-methylethyl]benzene, 1,4-bis[1-(4-hydroxyphenyl)-1-methylethyl]benzene, 4,6-bis[1-(4-hydroxyphenyl)-1-methylethyl]-1,3-dihydroxybenzene, 1,1-bis(4-hydroxyphenyl)-1-[4-[1-(4-hydroxyphenyl)-1-methylethyl]phenyl]ethane or the like, and 1,2-naphtoquinonediazide-4-sulfonic acid or 1,2-naphtoquinonediazide-5-sulfonic acid.

The naphtoquinonediazide compounds may be used alone or in combination with two or more kinds.

The photoacid generator is a compound causing formation of acid by irradiation with light. This acid acts on a cationic reactive group of the cationic crosslinking agent to form a crosslinking structure, and therefore the coating film containing the photoacid generator and the cationic crosslinking agent becomes sparingly soluble in the alkaline developer by irradiation with light.

Specific examples of the photoacid generator include an onium salt compound, a halogen-containing compound, a sulfone compound, a sulfonic acid compound, a sulfonimide compound and a diazomethane compound. Among these compounds, an onium salt compound or a halogen-containing compound is preferable because a cured film having excellent elongation physical properties can be formed.

Specific examples of the onium salt compounds include an iodonium salt, a sulfonium salt, a phosphonium salt, a diazonium salt and a pyridinium salt. Specific examples of a preferred onium salt compound include diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium p-toluenesulfonate, triphenylsulfonium hexafluoroantimonate, 4-t-buthylphenyl-diphenylsulfonium trifluoromethanesulfonate, 4-t-buthylphenyl-diphenylsulfonium p-toluenesulfonate, 4,7-di-n-butoxynaphthyltetrahydrothiophenium trifluoromethanesulfonate and 4-(phenylthio)phenyldiphenylsulfonium tris(pentafluoroethyl)trifluorophosphate.

Specific examples of the halogen-containing compound include a haloalkyl group-containing hydrocarbon compound and a haloalkyl group-containing heterocyclic compound. Specific examples of a preferred halogen-containing compound include: 1,10-dibromo-n-decane and 1,1-bis(4-chlorophenyl)-2,2,2-trichloroethane; and a s-triazine derivative such as phenyl-bis(trichloromethyl)-s-triazine, 4-methoxyphenyl-bis(trichloromethyl)-s-triazine, styryl-bis(trichloromethyl)-s-triazine and naphthyl-bis(trichloromethyl)-s-triazine.

Specific examples of the sulfone compound include a β-ketosulfone compound, a β-sulfonylsulfone compound and an α-diazo compound of these compounds. Specific examples of a preferred sulfone compound include 4-trisphenacyl sulfone, mesitylphenacyl sulfone and bis(phenacylsulfonyl)methane.

Specific examples of the sulfonic acid compound include alkyl sulfonates, haloalkyl sulfonates, aryl sulfonates and imino sulfonates. Specific examples of a preferred sulfonic acid compound include benzoin tosylate, pyrogallol tristrifluoromethanesulfonate, o-nitrobenzyl trifluoromethanesulfonate and o-nitrobenzyl p-toluenesulfonate.

Specific examples of the sulfonimide compound include N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hepto-5-ene-2,3-dicarboxyimide and N-(trifluoromethylsulfonyloxy)naphthylimide.

Specific examples of the diazomethane compound include bis(trifluoromethylsulfonyl)diazomethane, bis(cyclohexylsulfonyl)diazomethane and bis(phenylsulfonyl)diazomethane.

The photoacid generators may be used alone or in combination with two or more kinds.

The cationic crosslinking agent acts as a crosslinking component (curing component). Specific examples of the cationic crosslinking agent include a compound having two or more alkyl-etherized amino groups (hereinafter, also referred to as an “amino group-containing compound”), an oxirane ring-containing compound, an oxetane ring-containing compound, an isocyanate group-containing compound (including a blocked compound), an aldehyde group-containing phenolic compound and a methylol group-containing phenolic compound. However, a silane coupling agent having an epoxy group is excluded from the oxirane ring-containing compound, and a silane coupling agent having an isocyanate group is excluded from the isocyanate group-containing compound.

Specific examples of the alkyl-etherized amino group include a group represented by the following formula.

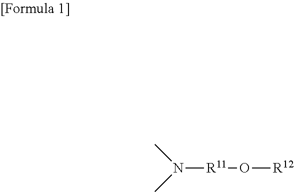

(wherein, R¹¹ represents a methylene group or an alkylene group, and R¹² represents an alkyl group.).

Specific examples of the amino group-containing compound include a compound in which an active methylol group (CH₂OH group) in a nitrogen compound is partially or wholly (at least two groups) is alkyl-etherized, such as (poly)methylolated melamine, (poly)methylolated glycoluril, (poly)methylolated benzoguanamine and (poly)methylolated urea. Here, specific examples of the alkyl group constituting alkyl ether include a methyl group, an ethyl group and a butyl group, and these groups may be the same with or different from each other. Moreover, a non-alkyl-etherized methylol group may be self-condensed within one molecule, or may be condensed between two molecules, resulting in forming an oligomer component. Specifically, hexamethoxymethyl melamine, hexabutoxymethyl melamine, tetramethoxymethyl glycoluril, tetrabutoxymethyl glycoluril or the like can be used.

The oxirane ring-containing compound is not particularly limited, as long as the compound contains an oxirane ring in a molecule, and specific examples thereof include a phenol novolak-type epoxy resin, a cresol novolak-type epoxy resin, a bisphenol-type epoxy resin, a trisphenol-type epoxy resin, a tetraphenol-type epoxy resin, a phenol-xylylene-type epoxy resin, a naphthol-xylylene-type epoxy resin, a phenol-naphthol-type epoxy resin, a phenol-dicyclopentadiene-type epoxy resin, an acyclic epoxy resin and an aliphatic epoxy resin.

Specific examples of the oxirane ring-containing compound include resorcinol diglycidyl ether, pentaerythritol glycidyl ether, trimethylolpropane polyglycidyl ether, glycerol polyglycidyl ether, phenyl glycidyl ether, neopentyl glycol diglycidyl ether, ethylene/polyethylene glycol diglycidyl ether, propylene/polypropylene glycol diglycidyl ether, 1,6-hexanediol diglycidyl ether, sorbitol polyglycidyl ether, propylene glycol diglycidyl ether and trimethylolpropane triglycidyl ether.

The oxetane ring-containing compound is not particularly limited, as long as the compound contains an oxetane ring in a molecule, and specific examples thereof include a compound represented by formulas (d-1) to (d-3) each.

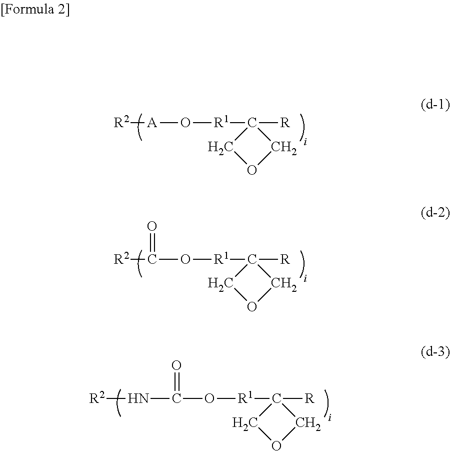

In the formulas (d-1) to (d-3), A represents a direct bond, or an alkylene group such as a methylene group, an ethylene group and a propylene group; R represents an alkyl group such as a methyl group, an ethyl group and a propyl group; R¹ represents an alkylene group such as a methylene group, an ethylene group and a propylene group; R² represents an alkyl group such as a methyl group, an ethyl group, a propyl group and a hexyl group; an aryl group such as a phenyl group and a xylyl group; a group represented by the following formula (where, R and R¹ are the same with R and R¹ in the formulas (d-1) to (d-3), respectively);

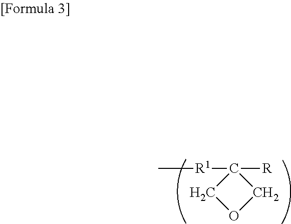

a dimethylsiloxane residue represented by the following formula (i): an alkylene group such as a methylene group, an ethylene group and a propylene group; a phenylene group; and a group represented by the following formulas (ii) to (vi); and i is equal to valence of R², and is an integer from 1 to 4. In addition, an asterisk “*” in the following formulas (i) to (vi) represents a bonding site.

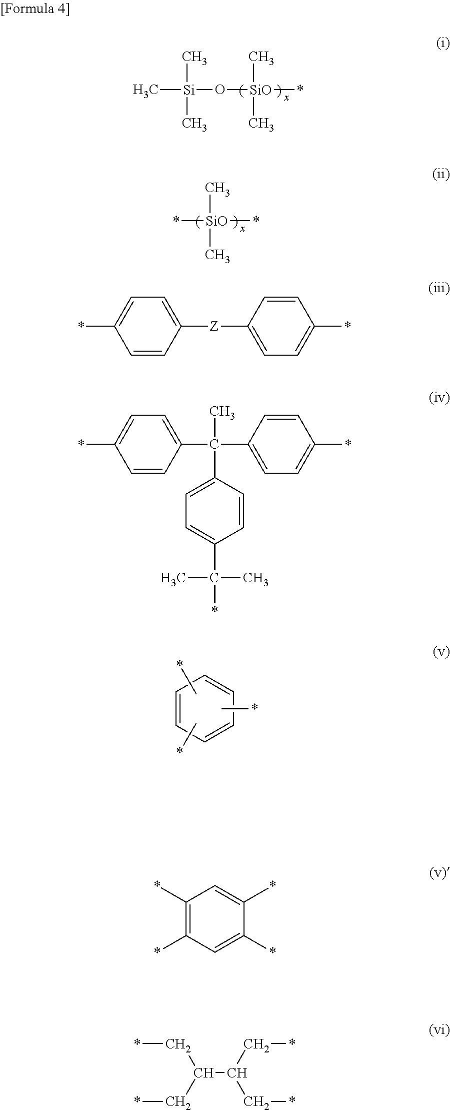

In the formulas (i) and (ii), x and y are each independently an integer from 0 to 50. In the formula (iii), Z is a direct bond or a divalent group represented by —O—, —CH₂—, —C(CH₃)₂—, —C(CF₃)₂—, —CO— or —SO₂—.

Specific examples of the compound represented by the formulas (d-1) to (d-3) each include 1,4-bis{[(3-ethyloxetane-3-yl)methoxy]methyl}benzene (trade name “OXT-121”, manufactured by Toagosei Co., Ltd.), 3-ethyl-3-{[(3-ethyloxetane-3-yl)methoxy]methyl}oxetane (trade name “OXT-221”, manufactured by Toagosei Co., Ltd.), 4,4′-bis[(3-ethyl-3-oxetanyl)methoxymethyl]biphenyl (trade name “ETERNACOLL OXBP”, manufactured by Ube Industries Ltd.), bis[(3-ethyl-3-oxetanylmethoxy)methyl-phenyl]ether, bis[(3-ethyl-3-oxetanylmethoxy)methyl-phenyl]propane, bis[(3-ethyl-3-oxetanylmethoxy)methyl-phenyl]sulfone, bis[(3-ethyl-3-oxetanylmethoxy)methyl-phenyl]ketone, bis[(3-ethyl-3-oxetanylmethoxy)methyl-phenyl]hexafluoropropane, tri[(3-ethyl-3-oxetanylmethoxy)methyl]benzene, tetra[(3-ethyl-3-oxetanylmethoxy)methyl]benzene, and a compound represented by the following formulas (d-a) to (d-d) each.

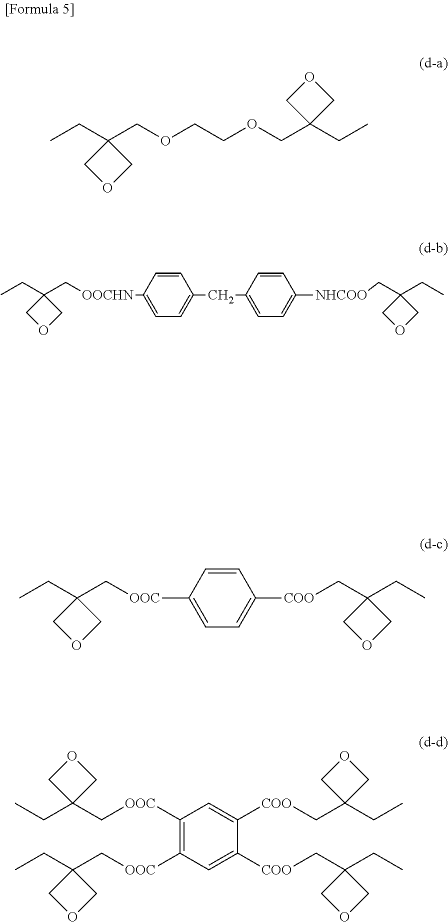

Moreover, in addition to these compounds, a high molecular weight compound having a polyvalent oxetane ring can be used. Specific examples thereof include an oxetane oligomer (trade name “Oligo-OXT”, manufactured by Toagosei Co., Ltd.) and a compound represented by formulas (d-e) to (d-g) each.

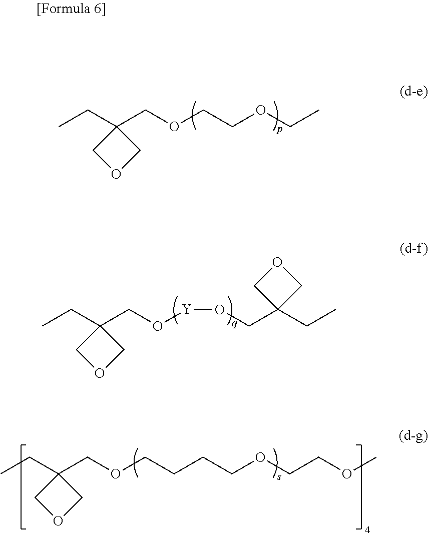

In the formulas (d-e) to (d-g), p, q and s are each independently an integer from 0 to 10,000, and are preferably an integer from 1 to 10. In the formula (d-f), Y is an alkylene group such as an ethylene group and a propylene group, or a group represented by —CH₂-Ph-CH₂— (where, Ph represents a phenylene group.).

The cationic crosslinking agents may be used alone or in combination with two or more kinds.

### (Step (2))

In the step (2), as shown in FIG. 1(2), resist 5 having an opening 4 in a region corresponding to each electrode pad 2 is formed by selectively exposing the coating film 3 to light and further developing the film.

More specifically, the opening 4 housing each electrode pad 2 is formed by partially exposing the coating film 3 to light and then developing the film so that the opening 4 housing each electrode pad 2 may be formed thereon. As a result, the resist 5 having the opening 4 in the region corresponding to each electrode pad 2 is obtained. The opening 4 is a hole penetrating through the resist 5. Exposure and development can be performed according to a conventional method. A maximum width of the opening 4 is ordinarily 0.1 to 10 times the film thickness of the coating film 3, and preferably one half to twice the film thickness thereof.

### (Step (3))

In the step (3), the opening 4 is filled with the molten solder while heating the molten solder. After cooling, as shown in FIG. 1(3), a solder electrode 6 is formed in each opening 4.

A method for filling the opening 4 with the molten solder while heating the molten solder is not particularly limited, and an ordinary filling method by the IMS method can be adopted. In the IMS method, the opening 4 is filled therewith while heating the molten solder ordinarily to 250° C. or more.

As described above, in the production process for the solder electrode according to the present invention, the photosensitive resin composition contains the benzoxazole precursor which is changed into a highly heat-resistant structure by heat, and therefore even when the opening 4 is filled with the molten solder by pressing the hot head onto the surface of the resist 5 as in the IMS method, development of the cracks on the surface of the resist 5 and development of the blisters can be suppressed.

The solder electrode produced according to the production process for the solder electrode of the present invention as described above is formed without developing the cracks and the blisters on the resist, and therefore an electrode adapted for the purpose without any disorder of a shape or the like is formed.

The production process for the solder electrode can further include a step (4) of removing the resist 5 from the substrate 1 after the step (3). FIG. 1(4) shows a state in which the resist 5 is removed from the substrate 1 after the step (3).

The solder electrode produced according to the production method for the solder electrode of the present invention can be used together with the resist 5 as shown in FIG. 1(3), or can also be used without the resist 5 as shown in FIG. 1(4).

<Production Process for a Laminate>

A first production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of forming a solder electrode by filling the opening with molten solder while heating the molten solder; and a step (5) of forming an electrical connection structure of the electrode pad of the first substrate and an electrode pad of a second substrate having the electrode pad through the solder electrode, wherein the photosensitive resin composition contains at least a benzoxazole precursor.

A second production process for a laminate according to the present invention includes: a step (1) of forming a coating film of a photosensitive resin composition on a first substrate having an electrode pad; a step (2) of forming resist having an opening in a region corresponding to the electrode pad by selectively exposing the coating film to light and further developing the film; a step (3) of forming a solder electrode by filling the opening with molten solder while heating the molten solder; a step (4) of removing the resist after the step (3); and a step (5) of forming an electrical connection structure of the electrode pad of the first substrate and an electrode pad of a second substrate having the electrode pad through the solder electrode after the step (4), wherein the photosensitive resin composition contains at least a benzoxazole precursor.

The steps (1) to (3) in the first production process for the laminate and the second production process therefor and the step (4) in the second production process for the laminate are substantially the same as the steps (1) to (5) in the production process for the solder electrode, respectively. More specifically, the first production process for the laminate is the process in which the step (5) is performed after the steps (1) to (3) in the production process for the solder electrode, and the second production process for the laminate is the process in which the step (5) is performed after the steps (1) to (4) in the production process for the solder electrode.

In the first and second production processes for the laminate, the substrate in the production process for the solder electrode corresponds to the first substrate.

In the first production process for the laminate, after the steps (1) to (3), the step (5) of forming the electrical connection structure between the electrode pad of the first substrate and the electrode pad of the second substrate having the electrode pad through the solder electrode is performed.

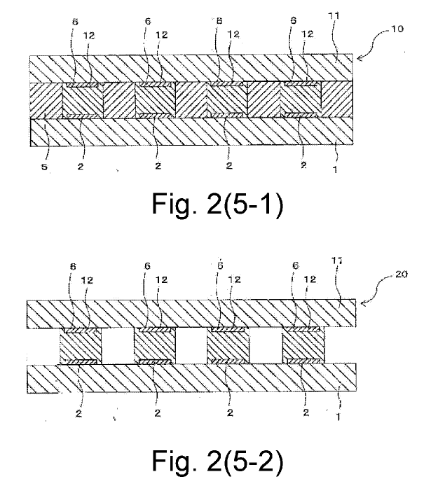

FIG. 2(5-1) shows a laminate 10 produced by the first production process for the laminate. The laminate 10 has an electrical connection structure formed by connecting the electrode pad 2 of the first substrate 1 and an electrode pad 12 of a second substrate 11 having the electrode pad 12 through the solder electrode 6 in a state shown in FIG. 1(3), which is produced by the steps (1) to (3).

The electrode pad 12 of the second substrate 11 is provided in a position facing the electrode pad 2 of the first substrate, when the first substrate 1 and the second substrate 11 are placed by facing surfaces on which the electrode pads are formed. The laminate 10 is obtained by forming the electrical connection structure by bringing the electrode pad 12 of the second substrate 11 into contact with the solder electrode 6 in the state shown in FIG. 1(3), and electrically connecting the electrode pad 2 of the first substrate 1 and the electrode pad 12 of the second substrate 11 through the solder electrode 6 by heating and/or pressuring the resulting material. The heating temperature is ordinarily 100 to 300° C., and force during the pressurization is ordinarily 0.1 to 10 MPa.

In the state shown in FIG. 1(3), the resist 5 is placed on the first substrate 1, and therefore the laminate 10 has the first substrate 1, the solder electrode 6, the second substrate 11, and the resist 5 interposed between the first substrate 1 and the second substrate 11.

In the second production process for the laminate, after the steps (1) to (4), the step (5) of forming the electrical connection structure between the electrode pad of the first substrate and the electrode pad of the second substrate having the electrode pad through the solder electrode is performed.

FIG. 2(5-2) shows a laminate 20 produced by the second production process for the laminate. The laminate 20 has an electrical connection structure formed by connecting the electrode pad 2 of the first substrate 1 and the electrode pad 12 of the second substrate 11 having the electrode pad 12 through the solder electrode 6 in a state shown in FIG. 1(4), which is produced by the steps (1) to (4).

The laminate 20 is obtained by forming the electrical connection structure by electrically connecting the electrode pad 2 of the first substrate 1 by bringing the electrode pad 12 of the second substrate 11 into contact with the solder electrode 6 in the state shown in FIG. 1(4) and the electrode pad 12 of the second substrate 11 through the solder electrode 6 by heating and/or pressurizing the resulting material.

In the state shown in FIG. 1(4), the resist 5 is not placed on the first substrate 1, and therefore the laminate 20 is formed of the first substrate 1, the solder electrode 6 and the second substrate 11.

As described above, the laminate produced by the production process for the laminate according to the present invention may have or need not have the resist between the first substrate and the second substrate. When the laminate has the resist as in the laminate 10, the resist is used as an underfill.

The laminate produced by the production process for the laminate according to the present invention has the electrical connection structure adapted for the purpose by the INS method, and thus selectivity of a solder composition is extended, and therefore the laminate can be applied to various electronic components, such as a semiconductor device, a display device and a power device.

The laminate produced by the production process for the laminate according to the present invention can be used in various electronic components, such as the semiconductor device, the display device and the power device.

### EXAMPLES

Hereinafter, the present invention is further specifically described with reference to the following Examples, but the present invention is in no way limited to those Examples. In the description of the following Examples, or the like, a term “part (s)” is used in the meaning of “part(s) by mass”.

### 1. Methods for Measuring Physical Properties

### (Method for Measuring Weight-Average Molecular Weight (Mw) of a Polybenzoxazole Precursor and an Alkali-Soluble Resin)

A weight-average molecular weight (Mw) of a polybenzoxazole precursor and an alkali-soluble resin was measured by gel permeation chromatography under the following conditions.
Column: TSK-M and TSK2500 being columns manufactured by Tosoh Corporation were connected in series
Solvent: tetrahydrofuran
Temperature: 40° C.
Detection method: refractive index method
Standard substance: polystyrene
GPC system: manufactured by Tosoh Corporation, system name “HLC-8220-GPC”

### 2. Preparation of Resist-Forming Composition

### [Synthesis Example 1] Synthesis of a Polybenzoxazole Precursor

In a flask, 20 g of isophthalic acid and 100 g of N-methyl pyrrolidone were put, and contents in the flask were cooled to 5° C., and then 29 g of thionyl chloride was added dropwise thereto, and the resulting mixture was reacted for 30 minutes to obtain a solution of isophthalic acid chloride.

Subsequently, 100 g of N-methyl pyrrolidone was put into the flask, 26 g of bis(3-amino-4-hydroxyphenyl) hexafluoropropane and 9 g of 1,3-bis(4-aminophenoxy)benzene were added thereto, and the resulting material was stirred and dissolved, and then 20 g of pyridine were added thereto. A temperature of the solution was kept at 5° C., and the solution of isophthalic acid chloride was added dropwise to this solution in 30 minutes, and then the resulting material was continuously stirred for 60 minutes and reacted. The resulting reaction mixture was charged into 3 L of water, a precipitate faulted was obtained by filtration, and then the precipitate was washed with pure water to obtain a polybenzoxazole precursor. A weight-average molecular weight of the polybenzoxazole precursor was 20,000.

### [Synthesis Example 2] Synthesis of an Alkali-Soluble Resin

In a nitrogen-purged flask equipped with a dry ice/methanol refluxing device, 5.0 g of 2,2′-azobisisobutyronitrile as a polymerization initiator and 90 g of diethylene glycol ethyl methyl ether as a polymerization solvent were put, and the resulting mixture was stirred. In the resulting solution, 10 g of methacrylic acid, 15 g of p-isopropenylphenol, 25 g of tricycle[5.2.1.0^{2,6}]decanyl methacrylate, 20 g of isobornyl acrylate and 30 g of n-butyl acrylate were added to start stirring, and a temperature was raised up to 80° C. Then, the resulting mixture was heated at 80° C. for 6 hours, and reacted.

After completion of heating, the reaction mixture was added dropwise into a large amount of cyclohexane to cause coagulation of the reaction product. The coagulated substance was washed with water, and the coagulated substance was redissolved into tetrahydrofuran in the same mass as the mass of the coagulated substance, and then the resulting solution was added dropwise into a large amount of cyclohexane to cause coagulation again. These redissolving and coagulation works were performed three times in total, and then the resulting coagulated substance was dried in vacuum at 40° C. for 48 hours to obtain an alkali-soluble resin. A weight-average molecular weight of the alkali-soluble resin was 10,000.

### [Example 1] Preparation of Photosensitive Resin Composition 1

Then, 100 parts of the polybenzoxazole precursor synthesized in the Synthesis Example 1, 10 parts of a condensation product of 1,1-bis (4-hydroxyphenyl)-1-[4-[1-(4-hydroxyphenyl)-1-methylethyl]phenyl]ethane with 1,2-naphtoquinonediazide-5-sulfonic acid (a mole ratio of the latter to the former: 2.0), and 100 parts of N-methyl-2-pyrrolidone were used, and these compounds were mixed and stirred to obtain a homogeneous solution. This solution was filtered through a capsule filter having a pore diameter of 10 μm to prepare a photosensitive resin composition 1.

### [Preparation Example 1] Preparation of Photosensitive Resin Composition 2

Then, 100 parts of the alkali-soluble resin synthesized in the Synthesis Example 2, 50 parts of polyester acrylate (trade name “ARONIX M-8060”, manufactured by Toagosei Co., Ltd.), 4 parts of diphenyl(2,4,6-trimethylbenzoyl)phosphine oxide (trade name “LUCIRIN TPO”, manufactured by BASF SE), 19 parts of 2,2-dimethoxy-1,2-diphenylethane-1-one (trade name “IRGACURE 651”, manufactured by BASF SE), and 80 parts of propylene glycol monomethyl ether acetate were used, and these compounds were mixed and stirred to obtain a homogeneous solution. This solution was filtered through a capsule filter having a pore diameter of 10 μm to prepare a photosensitive resin composition 2.

### Example 2

Onto a substrate having plural copper electrode pads on a silicon board, the photosensitive resin composition 1 prepared in Example 1 was coated by the use of a spin coater, and the resulting material was heated on a hot plate at 120° C. for 5 minutes to form a coating film having a thickness of 20 μm. Subsequently, this coating film was exposed to light having a wavelength of 420 nm at an irradiation intensity of 300 mJ/cm² through a pattern mask by the use of Aligner (manufactured by Suss Microtec SE, model “MA-200”). After exposure to light, the coating film was brought into contact with a 2.38 mass % tetramethylammonium hydroxide aqueous solution for 240 seconds, and the coating film was washed with running water and developed to form a resist holding substrate having openings in parts corresponding to the electrode pads. When observation by an electron microscope was carried out, an open tip of each opening had a circular shape having a diameter of 30 μm, and a depth of each opening was 20 μm. Moreover, a maximum width of the opening was 30 μm.

The resist holding substrate having openings was immersed into a 1 mass sulfuric acid aqueous solution at 23° C. for one minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that no cracks were found in the resist, and the openings were satisfactorily filled with the molten solder, and the solder electrode was satisfactorily formed.

Then, the resist holding substrate on which the solder electrode was formed was immersed into a solution obtained by mixing 90 parts of dimethyl sulfoxide, 3 parts of tetramethylammonium hydroxide and 7 parts of water to remove the resist from the substrate. A substrate equipped with a solder electrode obtained was washed with water and dried.

Another substrate having copper electrode pads was placed on the substrate having copper electrode pads through the solder electrode so that both may take an electrical connection structure. A pressure of 0.3 MPa was applied to two sheets of the substrates having the copper electrode pads by using a die bonder device at 250° C. for 30 seconds so that both may be fixed by applying pressure to produce a laminate consisting of the substrate having copper electrode pads, the solder electrode and the substrate having copper electrode pads in this order. When this laminate was observed by an electron microscope, it was confirmed that the material was the laminate having a well-formed electrical connection structure.

### Comparative Example 1

Onto a substrate having plural copper electrode pads on a silicon board, the photosensitive resin composition 2 prepared in Preparation Example 1 was coated by the use of a spin coater, and the resulting material was heated on a hot plate at 120° C. for 5 minutes to form a coating film having a thickness of 20 μm. Subsequently, this coating film was exposed to light having a wavelength of 420 nm at an irradiation intensity of 300 mJ/cm² through a pattern mask by the use of Aligner (manufactured by Suss Microtec SE, model “MA-200”). After exposure to light, the coating film was brought into contact with a 2.38 mass tetramethylammonium hydroxide aqueous solution for 240 seconds, and the coating film was washed with running water and developed to form a resist holding substrate having openings in parts corresponding to the electrode pads. When observation by an electron microscope was carried out, an open tip of each opening had a circular shape having a diameter of 30 μm, and a depth of each opening was 20 μm. Moreover, a maximum width of the openings was 30 μm.

The resist holding substrate having openings was immersed into a 1 mass sulfuric acid aqueous solution at 23° C. for 1 minute, and then washed with water and dried. The openings of the substrate after drying were filled with molten solder obtained by melting SAC305 (lead-free solder, trade name, manufactured by Senju Metal Industry Co., Ltd.) at 250° C. in 10 minutes while being heated to 250° C. When the resist holding substrate after being filled with the molten solder was observed by an electron microscope, it was confirmed that cracks were developed in the resist. Moreover, the openings were unable to be satisfactorily filled with the molten solder.

### REFERENCE SIGNS LIST

1, 11 Substrate
2, 12 Electrode pad
3 Coating Film
4 Opening
5 Resist
6 Solder electrode
10, 20 Laminate

1. A production process for a solder electrode, comprising:
a step (1) of forming a coating film of a photosensitive resin composition on a substrate having an electrode pad;
a step (2) of forming resist having an opening in a region corresponding to the electrode pad by selectively exposing the coating film to light and further developing the coating film; and
a step (3) of filling the opening with molten solder while heating the molten solder,
wherein the photosensitive resin composition contains at least a benzoxazole precursor.

2. The production process for the solder electrode as claimed in claim 1, wherein the benzoxazole precursor has a structure derived from dicarboxylic acid, and a structure derived from dihydroxydiamine.

3. The production process for the solder electrode as claimed in claim 2, wherein the dicarboxylic acid is aromatic dicarboxylic acid.

4. The production process for the solder electrode as claimed in claim 2, wherein the dihydroxydiamine is aromatic diamine.

5. The production process for the solder electrode as claimed in claim 1, wherein the photosensitive resin composition further contains a photosensitive agent.

6. The production process for the solder electrode as claimed in claim 5, wherein the photosensitive agent is a naphtoquinonediazide compound.

7. The production process for the solder electrode as claimed in claim 1, further comprising a step (4) of removing the resist.

8. A solder electrode, produced by the production process for the solder electrode as claimed in claim 1.

9. A production process for a laminate, comprising:
a step (1) of forming a coating film of a photosensitive resin composition on a first substrate having an electrode pad;
a step (2) of forming resist having an opening in a region corresponding to the electrode pad by selectively exposing the coating film to light and further developing the coating film;
a step (3) of forming a solder electrode by filling the opening with molten solder while heating the molten solder; and
a step (5) of forming an electrical connection structure of the electrode pad of the first substrate and an electrode pad of a second substrate having the electrode pad through the solder electrode,
wherein the photosensitive resin composition contains at least a benzoxazole precursor.

10. A production process for a laminate, comprising:
a step (1) of forming a coating film of a photosensitive resin composition on a first substrate having an electrode pad;
a step (2) of forming resist having an opening in a region corresponding to the electrode pad by selectively exposing the coating film to light and further developing the coating film;
a step (3) of forming a solder electrode by filling the opening with molten solder while heating the molten solder;
a step (4) of removing the resist after the step (3); and
a step (5) of forming an electrical connection structure of the electrode pad of the first substrate and an electrode pad of a second substrate having the electrode pad through the solder electrode after the step (4),
wherein the photosensitive resin composition contains at least a benzoxazole precursor.

11. A laminate, produced by the production process for the laminate as claimed in claim 9.

12. An electronic component, comprising the laminate as claimed in claim 11.

13. A photosensitive resin composition for injection molding solder, comprising at least a benzoxazole precursor.
